(19) United States
(12) Patent Application Publication
(10) Pub. No.: US 2009/0200070 A1
(43) Pub. Date: Aug. 13, 2009

(54) Cu-BASED WIRING MATERIAL AND ELECTRONIC COMPONENT USING THE SAME

(75) Inventors: Takahiko KATO, Hitachinaka (JP); Takashi NAITO, Funabashi (JP); Yuichi SAWAI, Mito (JP); Haruo AKAHOSHI, Hitachi (JP); Shinji YAMADA, Tsukuba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(73) Assignee: Hitachi, Ltd.

(21) Appl. No.: 12/366,707

(22) Filed: Feb. 6, 2009

(30) Foreign Application Priority Data
Feb. 8, 2008 (JP) 2008-028298

(51) Int. Cl. H05K 1/09; C23C 14/34; H01B 1/22

(52) U.S. Cl. 174/257; 204/298.13; 252/512

(57) ABSTRACT

An object of the present invention is to provide an electronic component, including a wiring that contacts a glass or a glass ceramics member, for which a Cu-based wiring material capable of suppressing generation of bubbles in the glass or the glass ceramics member and having excellent migration resistance is used. The present invention provides an electronic component including a wiring that contacts a glass or a glass ceramics member. In the electronic component, the wiring material is formed of a binary alloy made of two elements of Cu and Al, and contains not more than 50.0% by weight of Al and a balance of unavoidable impurities.

### BACKGROUND OF THE INVENTION

1. Field of the Invention

The present invention relates to a Cu-based wiring material that can suppress oxidization, and to an electronic component for which the wiring material is used for wiring.

2. Description of the Related Art

When electronic components having wirings, electrodes, etc. can be manufactured using a manufacturing process in which the electronic components do not contact an oxidizing atmosphere, pure Cu is used for a wiring or electrode material as represented by LSI wiring. On the other hand, in a typical manufacturing process for a large-sized plasma display or the like, a metal wiring is embedded in a glass dielectric, and the metal wiring is subjected to heat treatment in a high temperature range of, for example, not less than 400 degrees C. in an oxidizing atmosphere. For this reason, an Ag wiring or the like having resistance to oxidization even in the heat treatment at a high temperature has been practically used. Meanwhile, application of a Cu-based material having high reliability to the wiring is strongly desired from a viewpoint of cost reduction and improvement in migration resistance. However, when Cu is used, oxidization occurs at a temperature of over 200 degrees C., so that bubbles or the like are remarkably generated in the glass dielectric. Therefore, under the present circumstances, application of a pure Cu metal alone to the wiring has not been realized yet in the electronic component products accompanied by the manufacturing process at a high temperature in an oxidizing atmosphere.

In the conventional technique, an electronic component material has been known in which weatherability of Cu as a whole is improved by using Cu as a principal component, containing 0.1 to 3.0% by weight of Mo, and homogeneously mixing Mo in a grain boundary of Cu (for example, Japanese Patent Application Publication No. 2004-91907). In this conventional technique, addition of Mo is essential, and an attempt to further improve the weatherability compared with a case where Mo alone is added has been made by adding, in addition to Mo, a total amount of 0.1 to 3.0% by weight of one or multiple elements selected from the group consisting of Al, Au, Ag, Ti, Ni, Co, and Si. However, in this alloy, it has been pointed out that the weatherability rather deteriorates when adding the total amount of not less than 3.0% by weight of one or multiple elements selected from the group consisting of Al, Au, Ag, Ti, Ni, Co, and Si. Additionally, since addition of Mo is essential, there has been a problem that the material is high in cost, and is therefore not suitable for practical use in the electronic component products of a lower market cost.

### SUMMARY OF THE INVENTION

From the viewpoint of cost reduction and improvement in migration resistance, it is strongly desired to use a Cu-based material having higher reliability to the wiring as a material for a wiring, an electrode, or a contact part used for the electronic components. However, as mentioned above, when the Cu-based material is used as the wiring material or the electrode material in the electronic components having a configuration in which the wiring and the electrode coexist with glass or glass ceramics, there is a problem that bubbles are generated in the glass or glass ceramics in association with oxidization of the wiring material. This is because an oxide layer generated on a surface of a wiring, an electrode, or a contact part made of pure Cu reacts with the glass or glass ceramics that contacts this oxide layer at a high temperature, and as a result, bubbles are generated in the manufacturing process when the electronic components are manufactured with a method including a heat treatment process in an oxidizing atmosphere at a high temperature not less than 200 degrees C., and particularly, not less than 400 degrees C. Due to the generation of these bubbles, problems such as reduction of withstand voltage have arose, so that it has been difficult to manufacture these electronic components.

Based on the above-mentioned problems, an object of the present invention is to provide an electronic component, including a wiring that contacts a glass or a glass ceramics member, for which a Cu-based wiring material capable of suppressing generation of bubbles in the glass or the glass ceramics member and having excellent migration resistance is used.

Another object of the present invention is to provide a Cu-based wiring material that can suppress oxidization also in heat treatment in an oxidizing atmosphere, and can suppress increase in electric resistance.

The present invention provides an electronic component including a wiring that contacts a glass or a glass ceramics member. In the electronic component, the wiring is formed of a binary alloy made of two elements of Cu and Al, and contains not more than 50.0% by weight of Al and a balance of unavoidable impurities. Here, a structure of the wiring that contacts the glass or the glass ceramics member includes, for example, a structure in which the wiring is formed on a surface of the glass or the glass ceramics member, a structure in which a surface of the wiring is covered with the glass or the glass ceramics member, a structure in which the wiring is provided in a hole provided in the glass or the glass ceramics member, or the like.

Moreover, the present invention provides a wiring material obtained by mixing at least powders of a conductive metal material and glass powders and firing the mixture. In the wiring material, the conductive metal is composed of a binary alloy made of two elements of Cu and Al, and contains Al of not more than 50.0% by weight and the balance of unavoidable impurities.

According to the present invention, it is possible to provide an electronic component, including a wiring that contacts a glass or a glass ceramics member, for which a Cu-based wiring material capable of suppressing generation of bubbles in the glass or the glass ceramics member and having excellent migration resistance is used.

Furthermore, it is possible to provide a Cu-based wiring material that can suppress oxidization also in heat treatment in an oxidizing atmosphere, and can suppress increase in electric resistance.

### BRIEF DESCRIPTION OF THE DRAWINGS

FIG. 1 is a graph showing a relationship between an air exposure temperature and an amount of Al added to Cu, which shows a region where oxidation resistance is provided;

FIG. 2 shows results of an atmospheric exposure test;

FIG. 3 is a graph showing a relationship between a thickness of an oxide film and the amount of Al added to Cu;

FIG. 4 shows a generated state of bubbles generated in a dielectric glass on a pure Cu wiring;

FIG. 5 shows results of a test to check whether the bubbles are generated in the dielectric glass on pure Cu and on Cu—Al alloy materials;

FIG. 6 shows a detailed manufacturing process of an electronic component wiring produced by mixing particle powders of a conductive metal and glass powders;

FIG. 7 shows results obtained by observing pure Cu powers and Cu—Al alloy particle powders, which are produced using the atomizing method, by an SEM;

FIG. 8 shows results of thermal analysis of the pure Cu powders and Cu—Al alloy particle powders produced using the atomizing method;

FIG. 9 shows an influence of an amount of Al added to Cu on an electric resistance value of an electronic component wiring;

FIG. 10 is a sectional view of a plasma display for which a wiring material of the present invention is used;

FIG. 11 shows an influence of an amount of Cu—Al alloy powders in a mixture of conductive metal particle powders and glass powders on a resistivity of an electronic component wiring;

FIG. 12 is a sectional view of a plasma display for which the wiring material of the present invention produced by the sputtering method is used;

FIG. 13 shows a result of observation of bubbles generated in a dielectric glass from a comparative electronic component wiring for which pure Cu is used, by using an optical microscope;

FIG. 14 is a diagram showing an example of a sputtering target of the present invention;

FIG. 15 is a sectional view of a low temperature fired glass ceramic multilayer wiring board for which the wiring material of the present invention is used; and

FIG. 16 is a graph illustrating heat treatment conditions when firing a multilayer wiring board.

### DESCRIPTION OF THE PREFERRED EMBODIMENTS

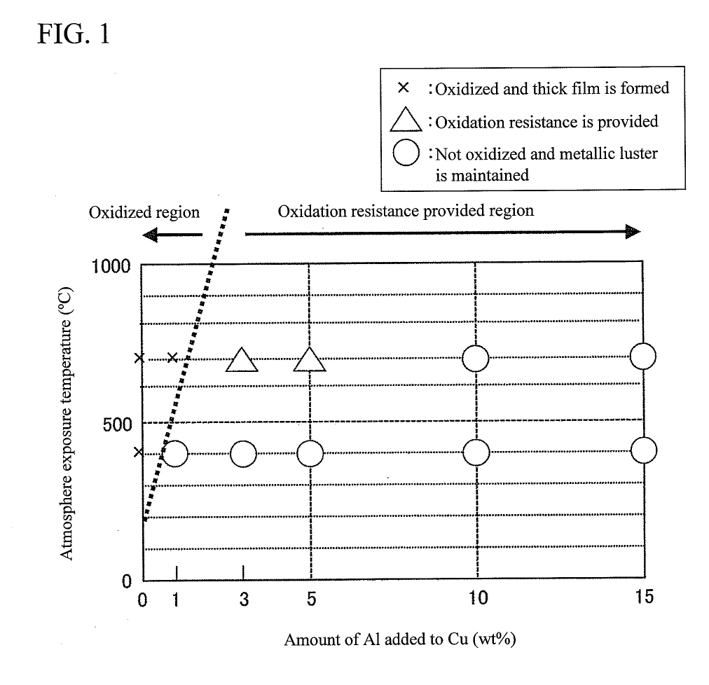

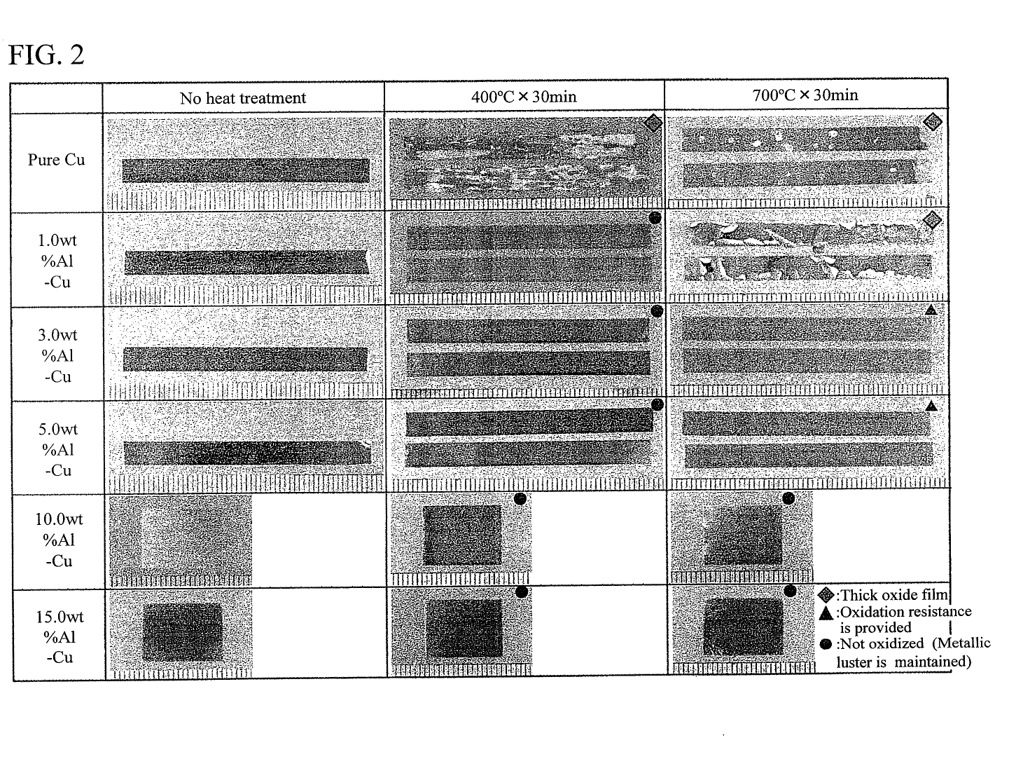

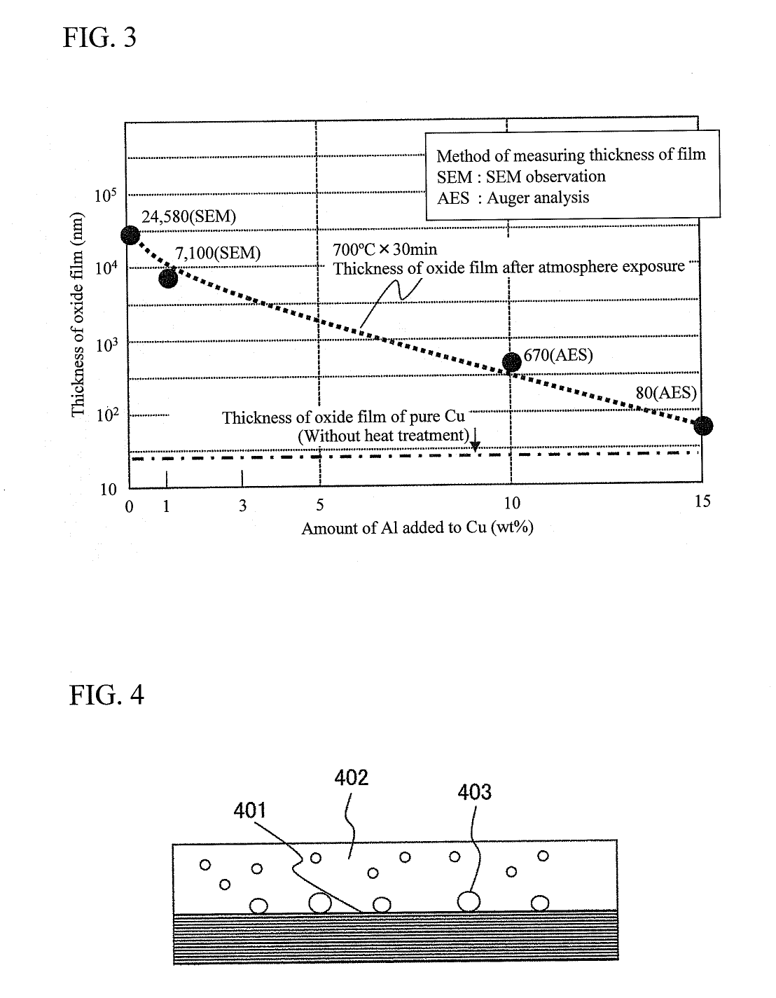

Hereinafter, detailed description will be given of research results by the present inventors that have led to the present invention, and embodiments of the present invention. FIGS. 1 and 2 show results of basic experiments performed to confirm an oxidation behavior of Cu and a situation where oxidation resistance was provided by addition of Al. As a specimen, a bulk material of a tape form was used, the bulk material obtained by rolling the material subjected to button melting to have a thickness of not more than 1 mm. An evaluation test of oxidation characteristic was an atmospheric high-temperature exposure test performed in an electric furnace. When a manufacturing process of an electronic component is taken into consideration, for example, in a component having a sputtering wiring structure that is in contact with a dielectric glass, the dielectric glass is softened and made to flow to seal the wiring. Therefore, heat treatment at a high temperature of not less than 400 degrees C. is performed. In a component in a molding form in which a wiring is formed in a thick film, glass powders softened and flowing are mixed with powders of a conductive metal to have a paste shape, and the obtained paste-like mixture is fired and molded. Therefore, heat treatment at approximately 700 degrees C. may be needed. Accordingly, air exposure temperatures of 400 degrees C. and 700 degrees C. were selected in consideration of the manufacturing process temperature for these general electronic components. As shown in FIGS. 1 and 2, it turns out that the oxidation behavior visually confirmed was more remarkable on a higher temperature side, while oxidation resistance was provided by addition of Al. FIG. 2 shows that in the case of pure Cu, a surface oxide film formed by heat treatment was thick, and coming off. In Cu to which 1.0% by weight of Al was added, oxidation resistance was provided on a lower temperature side, while a thick oxide film was coming off on the higher temperature side (700 degrees C.). On the other hand, in Cu to which 3.0% by weight of Al was added, the behavior that the surface oxide film was coming off was not observed even on the higher temperature side. Moreover, it turns out that as an amount of Al added increases as 5.0% by weight of Al, 10.0% by weight of Al, and 15.0% by weight of Al, more metallic luster is maintained and oxidation resistance is more excellent. In FIG. 3, in order to quantitatively grasp the behavior when oxidation resistance is given, using a specimen exposed in the atmosphere for 30 minutes at 700 degrees C., a thickness of the oxide film that came off from the surface was measured by SEM observation. Simultaneously, with respect to a sample from which the oxide film did not come off, the thickness of the oxide film was measured with the AES (Auger) analysis, and the thickness was plotted relative to an amount of Al added to Cu. It turns out that the thickness of the oxide film monotonically decreases with increase of the amount of added Al, and oxidation resistance increases. Furthermore, it turns out that extremely high oxidation resistance allowing the thickness of the oxide film comparable to that of a pure Cu sample not heat-treated was provided to a Cu sample to which 15.0% by weight of Al was added.

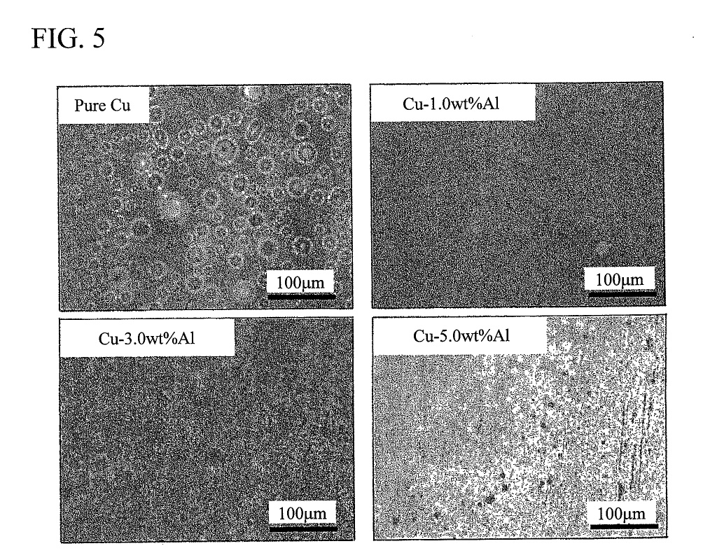

On the basis of the results of the basic experiments, the present inventors discovered that the binary alloy obtained by adding Al to Cu had extremely excellent anti-oxidation characteristics, and its applicability to the electronic components was examined. First, applicability to a component having a sputtering wiring structure in contact with a dielectric glass was experimentally confirmed. As shown in FIG. 4, a dielectric glass paste was embedded into binary Cu—Al alloys which has contents of pure Cu and a variety of Al and was produced by sputtering. The dielectric glass paste was then dried, and subsequently, heat-treated in the atmosphere for 30 minutes at 610 degrees C., to produce a sputtering wiring structure. The oxidation behavior of these Cu-based materials 401 was evaluated by observing a state of bubbles 403 generated in a dielectric layer 402 with an optical microscope. FIG. 4 schematically shows the cross section. FIG. 5 shows the result of observation with the optical microscope performed from a side of the dielectric layer 402 in FIG. 4. It is shown that countless bubbles were generated in pure Cu and oxidization remarkably progressed. By contrast, in Cu—Al alloys to which 1.0% by weight, 3.0% by weight, and 5.0% by weight of Al was respectively added, it is shown that no bubbles were generated and oxidization did not take place. From this result, it was confirmed that the Cu—Al alloy obtained by adding not less than 1.0% by weight of Al to Cu was applicable to a metal material for an electronic component formed of a conductive metal material in contact with the dielectric glass. However, in a sputtered film in which Al of an amount exceeding 50.0% by weight is added, sputtering of a uniform composition cannot be manufactured due to deposition of θ phase. When the amount of Al to be added exceeds 15.0% by weight, γ₂ phase becomes dominant, thus making it difficult to manufacture a sputtered film of a uniform composition. Accordingly, the Cu—Al alloy is applicable to the metal material for an electronic component by setting the amount of Al to be added to be not more than 50.0% by weight, and preferably, not more than 15.0% by weight.

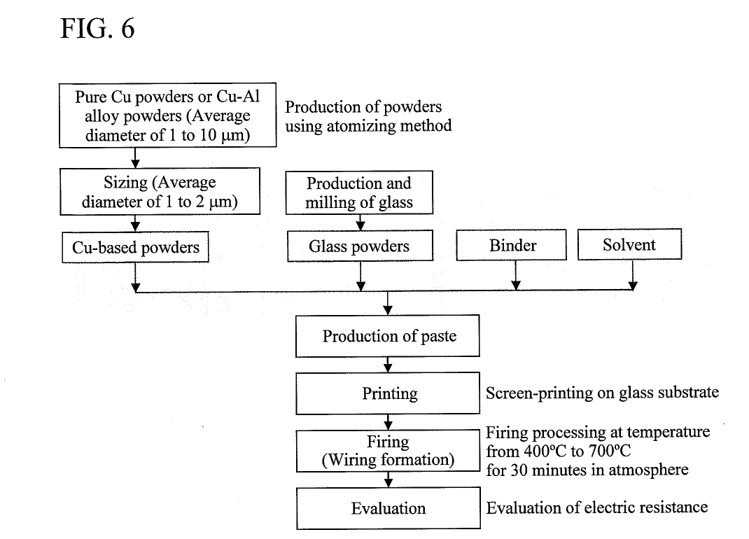

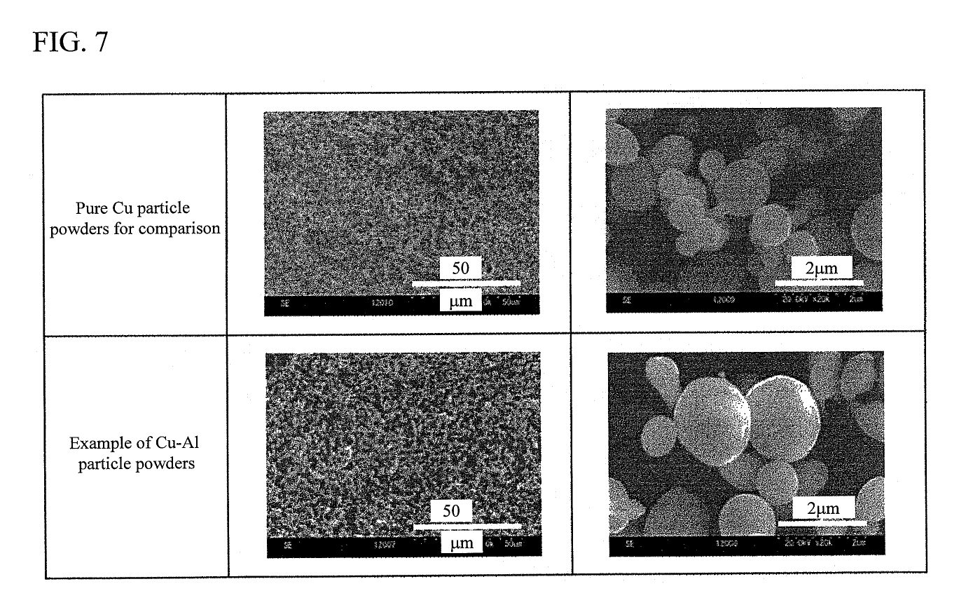

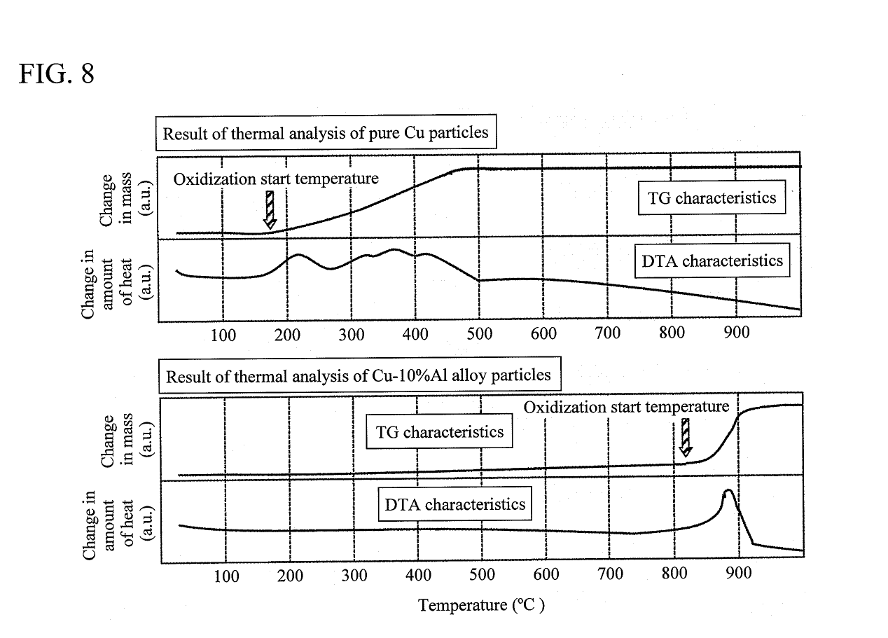

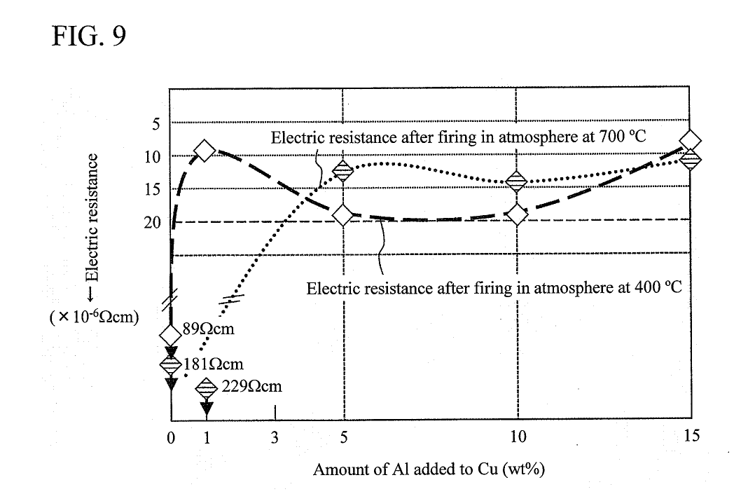

Second, examined was applicability of the Cu—Al alloy to a metal material for an electronic component formed of a conductive metal material produced by mixing powders of a conductive metal material and glass powders. FIG. 6 shows a detailed manufacturing process to manufacture the wirings of the electronic component obtained by mixing the glass powders with particle powders of a Cu—Al alloy produced by using the atomizing method as the powders of the conductive metal material, and obtained by mixing the glass powders with particle powders of pure Cu produced by using the atomizing method as a comparative material. For the particle powders, through sizing, the particle powders having a size not more than a wiring thickness were used. Here, the particle powders were sized to have an average particle diameter of 1 to 2 μm. These particle powders of the conductive metal material and glass powders were mixed with a binder and a solvent, thus obtaining a paste-like mixture. The wiring was formed using the mixture by the printing method, and fired in the atmosphere for 30 minutes at a temperature from 400 degrees C. to 700 degrees C. Then, final wiring formation was performed. Although various methods could be used for the final wiring formation, but the screen printing method was used here because of lower costs. In the wiring finally formed, electric resistance thereof was measured using the four-terminal method. FIG. 7 shows an SEM photograph of the particle powders subjected to the sizing of the particle powders. The particle powders of the Cu—Al alloy and the powders of pure Cu prepared as the comparative material had a spherical particle shape with a diameter of not more than approximately 2 μm. FIG. 8 shows results of measurement of the thermal analysis characteristics of the particle powders produced by using the atomizing method. Here, the result of Cu-10 wt % Al was shown as an example of the Cu—Al alloy particles. It turns out that oxidization progresses at a temperature of not more than 200 degrees C. in the particle powders of pure Cu, which is the comparative material. On the other hand, in the particle powders of the Cu-10 wt % Al alloy, it is clear that the oxidization phenomenon gradually appears at a temperature of not less than 800 degrees C., and it turns out that the Cu-10 wt % Al alloy has excellent oxidation resistance, even in a powder form. FIG. 9 shows a result of measurement of electric resistance of the wirings produced in the process of FIG. 6. In pure Cu, an electric resistance after firing at a temperature of 400 degrees C. was not less than 89 Ωcm, and an electric resistance after firing at a temperature of 700 degrees C. was not less than 181 Ωcm. In other words, pure Cu has an electric resistance value remarkably exceeding that of the same wiring made of Ag particles, and accordingly, cannot be used as an alternative to Ag wiring. Preferably, the electric resistance value of the wiring for the electronic component is not more than approximately 10⁻⁴ Ωcm. Furthermore, it turned out that the Cu wiring containing Al not less than 1% by weight has sufficient electric conductivity in the case of firing at a temperature of 400 degrees C., and the Cu wiring containing Al not less than 5% by weight has sufficient electric conductivity in the case of firing at a temperature of 700 degrees C. In other words, it turned out that the above-mentioned Cu wirings have the electric resistance value not more than that of the wiring made of the Ag particles, and can be used as an alternative to the Ag wiring. However, since it is difficult to produce Cu powders containing more than 50% by weight of Al with the atomizing method used when producing the particle powders, preferably, the amount of Al is not more than 15% by weight.

The above-mentioned results demonstrated that the wirings, electrodes, contact parts, or the like that do not oxidize can be manufactured by using a conductive metal material, with a material configuration in which the conductive metal material and the glass or glass ceramics coexist, for an electric component product manufactured as follows: the conductive metal material is exposed to an oxidizing atmosphere during the manufacturing process, and is subjected to a heat treatment process at a high temperature of not less than 200 degrees C., the conductive metal material made of two elements Cu and Al, and containing not more than 50.0% by weight of Al, preferably, 1.0 to 15.0% by weight of Al, and a balance of unavoidable impurities. Accordingly, the Cu-based wirings, electrodes, and contact parts that do not oxidize can be manufactured by using the metal material for an electronic component of the present invention, with a material configuration in which the conductive metal material and the glass or glass ceramics coexist, for the electronic component product manufactured by the method, in which the conductive metal material is exposed to an oxidizing atmosphere during the manufacturing process, and is subjected to the heat treatment process at the high temperature of not less than 200 degrees C., more substantially, not less than 400 degrees C. Accordingly, it is possible to provide the electronic component that is inexpensive and has excellent migration resistance and high reliability. In the heat treatment process at the high temperature, an upper limit of the temperature at which the alloy of the present invention does not oxidize can be raised with increase of the amount of Al to be added. For example, when 10% by weight of Al is added to Cu, as has been already shown in FIG. 8, it is possible to increase the temperature in the heat treatment process to a temperature of not less than 800 degrees C. Moreover, when not less than 15% by weight of Al is added, it is possible to obtain an alloy that does not oxidize in the heat treatment process even at a temperature of not less than 900 degrees C. The wirings, electrodes, and contact parts formed with the metal material for an electronic component of the present invention may be a part of or all of a system on film (SOF), a tape carrier package (TCP), a low temperature co-fired ceramics (LTCC), a plasma display (PDP), a liquid crystal display (LCD), an organic EL (electroluminescence) display, and electronic components that form a solar cell. In the above-mentioned components, the anti-oxidation characteristics of the present invention are effectively demonstrated.

Examples showing the best mode of the present invention will be given below.

### EXAMPLE 1

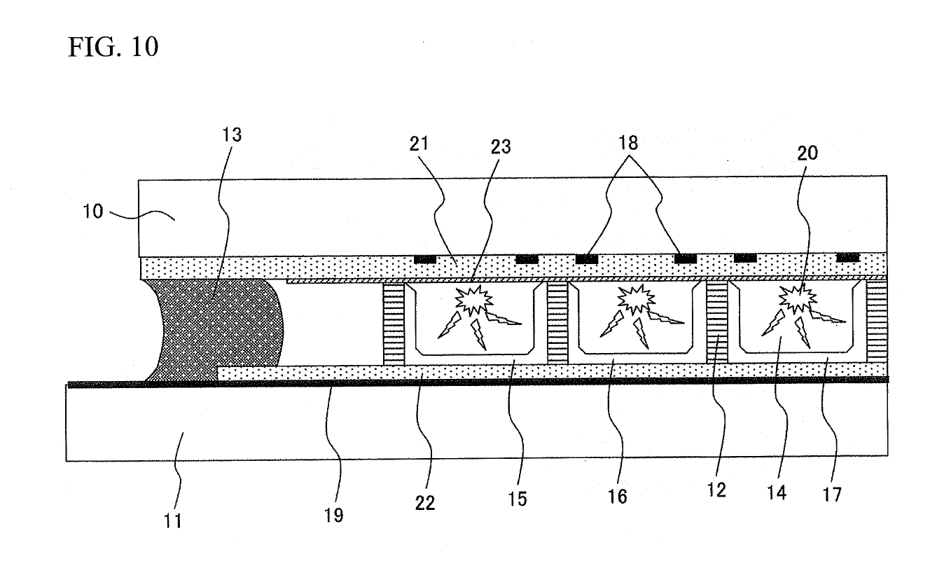

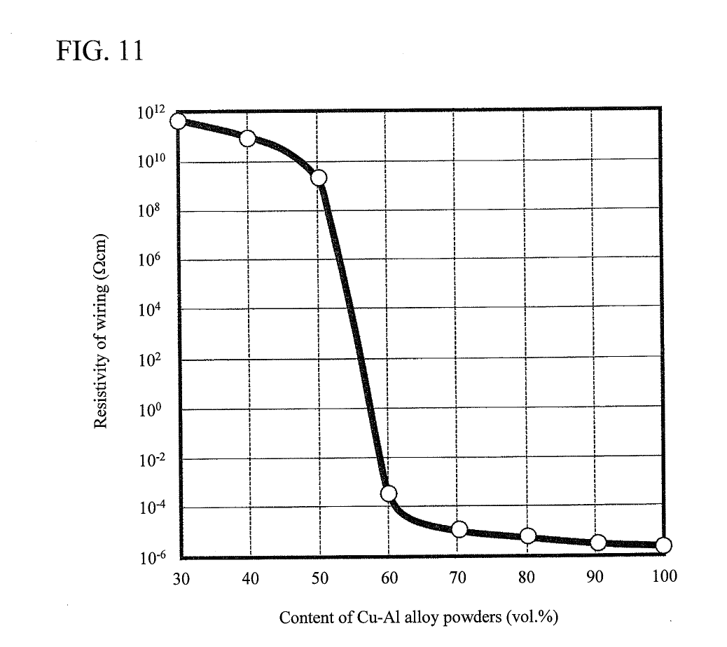

Description will be given of an example in which the present invention is applied to a plasma display panel. FIG. 10 shows an outline of a sectional view of the plasma display panel.

In the plasma display panel, a front plate 10 and a back plate 11 are disposed to face each other with a gap of 100 to 150 μm. The gap between the substrates (front plate 10 and back plate 11) is maintained by partition walls 12. A periphery of the front plate 10 and the back plate 11 is airtightly sealed with a sealing material 13, and an inside of the panel is filled with a rare gas. Each fine space (cell 14) divided by the partition wall 12 is filled with a fluorescent body. One pixel is formed of the cells of three colors respectively filled with fluorescent bodies 15, 16, and 17 of red, green, and blue. Each pixel emits light of corresponding color in response to a signal.

Electrodes regularly arranged are provided on the glass substrate of the front plate 10 and the back plate 11. A display electrode 18 of the front plate 10 and an address electrode 19 of the back plate 11 form a pair. Image information is displayed by selectively applying a voltage of 100 to 200V between the display electrode 18 and the address electrode 19 in response to a display signal, and by generating an ultraviolet ray 20 by electric discharge between the display electrode 18 and the address electrode 19 to cause the fluorescent bodies 15, 16, and 17 to emit light. The display electrode 18 and the address electrode 19 are covered with dielectric layers 21 and 22 for protection of these electrodes, control of wall charges at the time of electric discharge, etc. A thick film of a glass is used for the dielectric layers 21 and 22.

In order to form the cells 14, the back plate 11 is provided with the partition walls 12 on the dielectric layer 22 of the address electrode 19. This partition wall 12 is a structure having a stripe shape or a box shape.

Generally, at present, the Ag thick film wiring is used for the display electrode 18 and the address electrode 19. Change to the Cu thick film wiring from the Ag thick film wiring is preferable for cost reduction and countermeasures against migration of Ag, as mentioned above. Conditions necessary for this change are that Cu does not oxidize and electric resistance does not reduce at the time of forming and firing the Cu thick film wiring in an oxidizing atmosphere, that Cu does not oxidize and the electric resistance does not reduce due to reaction of Cu with the dielectric layer at the time of forming and firing the dielectric layer in the oxidizing atmosphere, and further, that withstand voltage does not reduce due to voids (bubbles) generated in the vicinity of the Cu thick film wiring. Although the display electrode 18 and the address electrode 19 can be also formed by the sputtering method, the printing method is advantageous for price reduction. The dielectric layers 21 and 22 are generally formed by the printing method. The display electrode 18, the address electrode 19, and the dielectric layers 21 and 22, which are formed by the printing method, are usually fired at a temperature in a range from 450 to 620 degrees C. in the oxidizing atmosphere.

The display electrode 18 is formed on the surface of the front plate 10 so as to intersect perpendicular to the address electrode 19 of the back plate 11, and subsequently, the dielectric layer 21 is formed on the whole surface of the front plate 10. On the dielectric layer 21, a protective layer 23 is formed in order to protect the display electrode 18 and the like from electric discharge. Generally, a vapor deposition film of MgO is used for the protective layer 23. On the other hand, the address electrode 19 is formed on the back plate 11. Subsequently, the dielectric layer 22 is formed in a cell formation region, and the partition wall 12 is provided on the dielectric layer 22. The partition wall 12 made of a glass structure body is made of a structural material containing at least a glass composition and a filler, and is formed of a burned substance obtained by sintering the structural material. By attaching a volatile sheet having grooves to a partition wall part, pouring a paste for the partition wall into the grooves, and firing the paste at 500 to 600 degrees C., the partition wall 12 can be formed while volatilizing the volatile sheet. The partition wall 12 can also be formed by applying the paste for the partition wall onto the whole surface by the printing method, drying the paste, masking, removing an unnecessary part with sandblasting or chemical etching, and firing at a temperature from 500 to 600 degrees C. The fluorescent bodies 15, 16, and 17 are respectively formed by respectively charging pastes of colors for the fluorescent bodies 15, 16, and 17 into the cells 14 divided by the partition walls 12, and firing the pastes at a temperature from 450 to 500 degrees C.

Usually, the front plate 10 and the back plate 11 separately produced are deposited to face each other, and are accurately positioned to each other. Then, the peripheries of the front plate 10 and the back plate 11 are glass-sealed at a temperature from 420 to 500 degrees C. The sealing material 13 is formed in one of the peripheries of the front plate 10 and the back plate 11 in advance by the dispenser method or the printing method. Generally, the sealing material 13 is formed on the side of the back plate 11. Moreover, the sealing material 13 may be temporarily fired in advance simultaneously with firing of the fluorescent bodies 15, 16, and 17. By taking this method, bubbles in the glass-sealed part can be remarkably reduced, and the glass-sealed part having high airtightness, i.e., high reliability can be obtained. In glass sealing, gas inside the cell 14 is exhausted while being heated, and a rare gas is sealed. Thereby, the panel is completed. When temporarily firing the sealing material 13 and glass sealing, the sealing material 13 may contact directly the display electrode 18 and/or the address electrode 19. It is not preferable that the electric resistance of the wiring material increase due to a reaction of the sealing material 13 with a wiring material that forms the electrodes. Therefore, it is necessary to prevent this reaction.

In order to light the completed panel, a voltage is applied to a part where the display electrode 18 and the address electrode 19 intersect to cause electric discharge of the rare gas within the cell 14 and generate a plasma state. Then, the ultraviolet ray 20 generated when the rare gas within the cell 14 returns from the plasma state to the original state is used to cause light emission of the fluorescent bodies 15, 16, and 17. Thereby, the panel is lit, and the image information is displayed. When lighting each color, address discharge is performed between the display electrode 18 and the address electrode 19 of the cell 14 desired to be lit, and wall charges are accumulated in the cell. Then, by applying a fixed voltage to a pair of the display electrodes, display discharge occurs only in the cell in which the wall charges were accumulated due to the address discharge. Thereby, the ultraviolet ray 20 is generated to cause light emission of the fluorescent body in the cell. The image information is displayed with the above-mentioned mechanism.

First of all, it was examined in advance whether the wiring material made of the powders of the Cu—Al alloy of the present invention and the glass powders could be applied to the display electrode 18 of the front plate 10 and the address electrode 19 of the back plate 11. The Cu—Al alloy powders having an average particle diameter of 1 to 2 μm and the glass powders having an average particle diameter of 1 μm were blended at a variety of ratios, and a binder and a solvent were further added to produce a paste for wiring. For the glass powders, an unleaded low softening point glass having a softening point around 450 degrees C. was used. Moreover, ethyl cellulose was used as the binder, and butyl carbitol acetate was used as the solvent. The produced paste for wiring was applied onto the glass substrate to be used for the plasma display panel by using the printing method, and the glass substrate was heated at 530 degrees C. in the atmosphere for 30 minutes to form the wiring. The electric resistance value of the produced wiring was measured, and a resistivity was obtained. FIG. 11 shows a relationship between a content of the Cu—Al alloy powders of the present invention and the resistivity of the wiring. It could be confirmed that the wiring containing the Cu—Al alloy powders not less than 65% by volume (containing the glass powders not more than 35% by volume) hardly oxidized, and the resistivity of the wiring was sufficiently low. Accordingly, the powders of the Cu—Al alloy of the present invention can be used as the wiring material by containing the glass powders not more than 35% by volume. In this case, oxidation resistance can be provided by adding Al of not less than 1.0% by weight to Cu in a chemical composition of the Cu—Al alloy powders. However, preferably, by adding up to 15.0% by weight of Al, sufficient oxidation resistance can be ensured. Note that, however, addition of Al of an amount exceeding 50.0% by weight causes problems in production of the alloy powders, and it is not preferable in the case of a sputtered film from a viewpoint of homogeneity of film quality.

When the content of the glass powders in the wiring was small, the wiring easily came off from the glass substrates which are the front plate and the back plate. When the content of the glass powder was not less than 10% by volume, the wiring could be firmly formed on the glass substrate. In other words, the wiring material that can be effectively used is obtained by containing 65 to 90% by volume of the Cu—Al alloy powders and 10 to 35% by volume of the glass powders. Additionally, when powders of a low thermal expansion filler are mixed with the wiring material, it becomes more difficult for the wiring to come off. However, the resistivity increases when the filler powders are mixed. Therefore, usually, the amount of the filler powders to be mixed is needed to be not more than 20% by volume.

As a comparative example for check, an experiment was performed in a similar manner by using the powders of pure Cu as the wiring material. By heating at 530 degrees C. in the atmosphere, pure Cu was remarkably oxidized, and it could not be used as the wiring material.

From the above-mentioned examined result, the wiring material made of 85% by volume of the Cu—Al alloy powders having an average particle diameter of 1 to 2 μm and 15% by volume of the glass powders having an average particle diameter of 1 μm was selected, and the wiring material was used for the display electrode 18 of the front plate 10 and the address electrode 19 of the back plate 11. Thereby, the plasma display panel shown in FIG. 10 was produced as an experiment. Similarly to the above-mentioned case, the paste for wiring was obtained by mixing ethyl cellulose as the binder and butyl carbitol acetate as the solvent for this wiring material. The display electrode 18 and the address electrode 19 were formed by applying the paste thus made onto the front plate 10 and the back plate 11 by the printing method and firing the paste at 530 degrees C. in the atmosphere for 30 minutes. Furthermore, the display electrode 18 and the address electrode 19 were covered with a glass of the dielectric layers 21 and 22. The glass of the dielectric layers 21 and 22 was formed in a similar manner by adding the binder and the solvent to the glass powders having an average particle diameter of 1 μm to make a paste, applying the paste thus made almost the whole surface by the printing method, and firing the paste at 610 degrees C. in the atmosphere for 30 minutes. Nonleaded glass having a softening point around 560 degrees C. was used for the glass powder. Moreover, ethyl cellulose was used as the binder, and butyl carbitol acetate was used as the solvent. Then, the front plate 10 and the back plate 11 were separately produced, and the peripheral part was glass-sealed. Thereby, the plasma display panel was produced. It turned out that the display electrode 18 and the address electrode 19 formed by using the wiring material of the present invention have neither discoloration due to oxidization nor generation of voids in an interface part between the display electrode 18 and the dielectric layer 21 and that between the address electrode 19 and the dielectric layer 22, and thus can be mounted on the panel.

Subsequently, a lighting test of the produced plasma display panel was performed. The panel could be lit without increasing the electric resistance of the display electrode 18 and the address electrode 19, without reducing the withstand voltage, and further, without migration as Ag. Besides these, no problematic point was observed.

The wiring material of the present invention is not limited to the wiring material for the plasma display panel, but can also be used for the wiring material for a solar cell or the like. Under the present circumstances, a wiring material made of Ag powders and glass powders is used for wiring of the solar cell. By changing the current wiring material to the wiring material of the present invention, costs can be significantly reduced.

### EXAMPLE 2

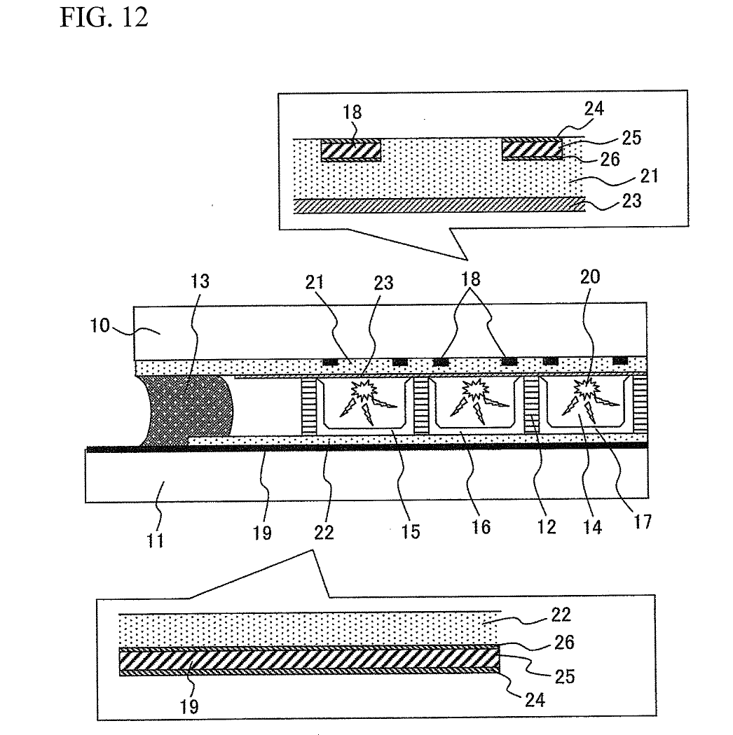

In the plasma display panel of FIG. 10 produced in example 1, a wiring material was formed by using the sputtering method for the display electrode 18 and the address electrode 19. As shown in FIG. 12, the wiring material had a three-layered structure obtained by sequentially forming a metal Cr film 24, a Cu—Al alloy film 25 of the present invention, and a metal Cr film 26 again. The metal Cr film 24 of the first layer was formed in order to improve adhesion of the front plate 10 to the Cu—Al alloy film 25 and the back plate 11 to the Cu—Al alloy film 25. Moreover, the metal Cr film 26 of the third layer was formed in order to improve wettability with the dielectric layers 21 and 22. The metal Cr film 24 of the first layer had a thickness of 0.2 μm, the Cu—Al alloy film 25 of the second layer had a thickness of 3.0 μm, and the metal Cr film 26 of the third layer had a thickness of 0.1 μm. The plasma display panel was produced and evaluated in the same manner as in the case of example 1. A disk made of a bulk material of metal Cr and a bulk material of a Cu—Al alloy were used for a sputtering target to form the respective layers.

It turned out that the display electrode 18 and the address electrode 19 formed by using the wiring material of the present invention have no void in the side portions thereof, and can be mounted on the panel. Subsequently, the lighting test of the produced plasma display panel was performed. As a result, the panel could be lit without increasing the electric resistance of the display electrode 18 and the address electrode 19, without reducing the withstand voltage, and further, without migration as Ag. Besides these, no problematic point was observed.

As a comparative example for check, a pure Cu film was used instead of the Cu—Al alloy film 25 of the second layer of the wiring material to form the display electrode 18 and the address electrode 19, and the panel was produced as an experiment in a same manner as mentioned above. A lot of parts where voids were generated were observed at an interface part between the side portions of the display electrode 18 and the dielectric layer 21 and that between the side portions of the address electrode 19 and the dielectric layer 22. In addition, the withstand voltage was decreased to half.

Since a satisfactory panel evaluation result was obtained using the display electrode 18 and the address electrode 19 formed of the above-mentioned three-layered wiring formed by the sputtering method, then, a two-layered wiring from which the metal Cr film 26 of the third layer was removed was used to form the display electrode 18 and the address electrode 19, and the plasma display panel of FIG. 10 was produced. In a similar manner to the above-mentioned case, the metal Cr film 24 of the first layer had a thickness of 0.2 μm, and the Cu—Al alloy film 25 of the second layer had a thickness of 3.0 μm. It turned out that the display electrode 18 and the address electrode 19 formed by using the wiring material of the present invention have neither discoloration due to oxidization nor generation of voids in an interface part between the display electrode 18 and the dielectric layer 21 and that between the address electrode 19 and the dielectric layer 22, and can be mounted on the panel. Subsequently, a lighting test of the produced plasma display panel was performed. As the result, no problematic point was observed in a same manner as mentioned above, and it turned out that a satisfactory panel can be also manufactured by using the two-layered wiring.

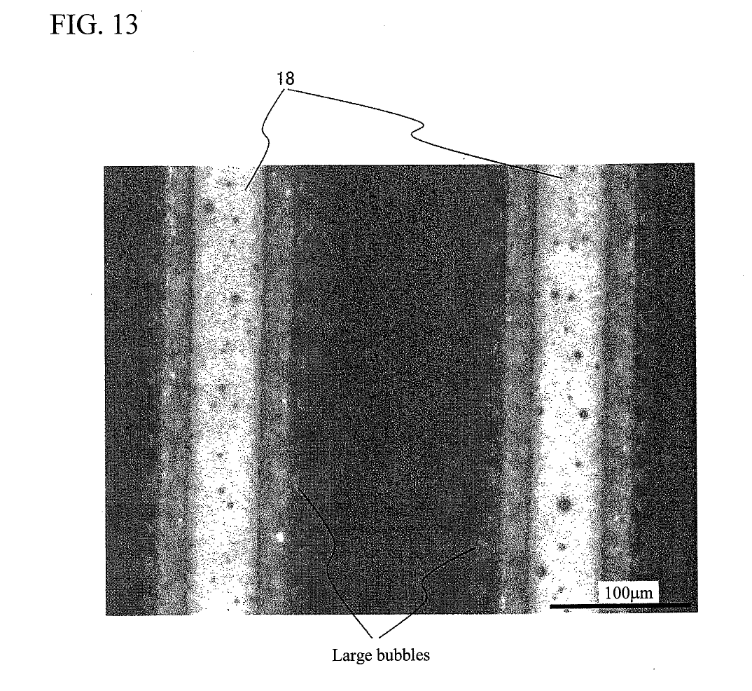

Also in this case, as a comparative example for check, a pure Cu film was used instead of the Cu—Al alloy film 25 of the second layer of the wiring material to form the display electrode 18 and the address electrode 19, and the panel was produced as an experiment in a same manner as the above-mentioned case. The pure Cu film in the display electrode 18 and the address electrode 19 were remarkably oxidized. Moreover, many voids were generated at an interface part between the display electrode 18 and the dielectric layer 21 and that between the address electrode 19 and the dielectric layer 22. FIG. 13 shows a result, observed with an optical microscope, of large bubbles generated between the wiring formed by using the pure Cu film and the dielectric layer. These large bubbles are generated by reacting the dielectric layer with an oxide layer generated on the surface of the wiring material at a high temperature. Consequently, the pure Cu wiring could not be used for the panel.

As mentioned above, irrespective of existence of Cr of the uppermost layer, generation of the bubbles due to reaction with the dielectric layer can be suppressed by using the display electrode formed using the Cu—Al alloy with Cr being the lowermost layer. When the lowermost layer is a Cr oxide layer, adhesion between the Cu—Al alloy and the back plate can be maintained in the same manner. The Cr oxide layer having an adjusted thickness is used for the lowermost layer, and reflected light from the surface of the Cr oxide layer is caused to interfere with reflected light from the surface of the Cu—Al alloy. Thereby, a color tone of the display electrode observed from the front can be adjusted, and for example, black to dark color and brown can be obtained.

### EXAMPLE 3

In experimental production of the panel of example 2, the sputtering target of the Cu—Al alloy film used for the wiring material was examined. In example 2, the sputtering target made of the Cu—Al alloy was used. In this example, using a sputtering target other than this, it was confirmed whether a desired Cu—Al alloy film could be formed.

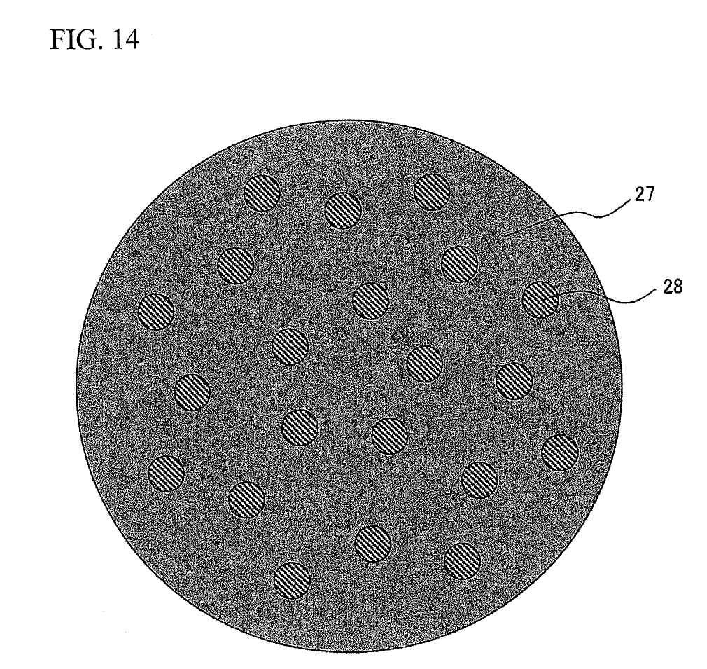

First, as shown in FIG. 14, a sputtering target was manufactured, in which Cu and Al did not form an alloy but each of Cu and Al independently forms a target as a single metal. This sputtering target was obtained by making many through holes in a disk 27 of pure Cu, sealing the through holes with pure Al 28 fitted to a shape of the through hole, and polishing the surface. With respect to filling of the pure Al into the pure Cu disk, size of the through hole and the number of the through holes were determined in consideration of composition homogeneity of a sputtered film. While the shape of the through hole is circular (cylindrical) in FIG. 14, the shape of the through hole may be strip-like (rectangular parallelepiped). Furthermore, a target made of alternately combined Cu metal and Al metal both having a sector as a shape on the target surface may be used. As a result of forming the film by using this sputtering target, Cu and Al were mixed at a desired concentration in composition, and a Cu—Al alloy film equal to that formed using the sputtering target made of the Cu—Al alloy was obtained. In other words, it turned out that a sputtered film that has small change in resistance due to oxidization and that cannot easily react with the glass of the dielectric layer can be obtained even when the sputtering target of this example is used. Additionally, a Cu—Al alloy containing a predetermined amount of Al can also be formed with multiple sputtering targets using a sputtering target of single Cu and a sputtering target of single Al. In this case, a method of performing sputtering while rotating the multiple sputtering targets can be used. Alternatively, a method of repeating sputtering of Al and Cu while replacing the target to be sputtered, forming a laminated film made of Al and Cu, and heat-treating the laminated film to form a Cu—Al alloy can be used.

The sputtering target of this example can be inexpensively manufactured compared to the sputtering target made of the Cu—Al alloy. It is necessary to manufacture the sputtering target made of the Cu—Al alloy from a bulk source material of the Cu—Al alloy. On the other hand, advantageously, the sputtering target of this example can be manufactured by combining pure Cu and pure Al that are widely spread.

### EXAMPLE 4

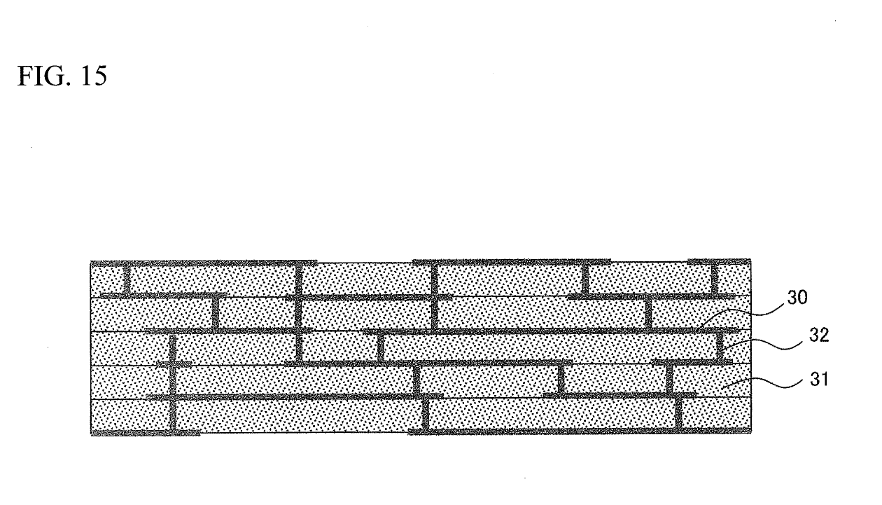

In this example, a multilayer wiring board (five layers) of LTCC (Low Temperature Co-fired Ceramics) shown in FIG. 15 was manufactured. A wiring 30 is formed in three dimensions. In this manufacturing method, first, a green sheet 31 made of glass powders and ceramics powders is produced, and through holes 32 are opened in desired positions. Then, a paste for the wiring 30 is applied by the printing method, and simultaneously, the through holes 32 are filled also with the paste. The paste for the wiring 30 is applied also to a back surface of the green sheet 31 by the printing method, when necessary. In this case, after drying the paste for the wiring 30 applied to the surface, application to the back surface is performed. The green sheets 31 each having the paste for the wiring 30 applied thereon are stacked. Then, the stacked body is fired usually at a temperature around 900 degrees C. in the atmosphere, and the multilayer wiring board of LTCC is manufactured. For the paste for the wiring 30, an expensive Ag paste is usually used. When using a Cu paste that has advantages in countermeasures against migration and is inexpensive, firing is performed in a nitrogen atmosphere. However, removal of a binder cannot be performed well, and it has been difficult to obtain a fine multilayer wiring board. Moreover, there has been a problem that Cu is oxidized by softening and flowing of the glass in a part of the green sheet 31 where the glass contacts the Cu wiring 30, thereby increasing the electric resistance of the wiring 30. Additionally, there has been another problem that voids are generated by reaction with the glass at an interface part between the glass and the wiring 30. The generation of the voids which may disconnect the wiring 30 is not a preferable phenomenon.

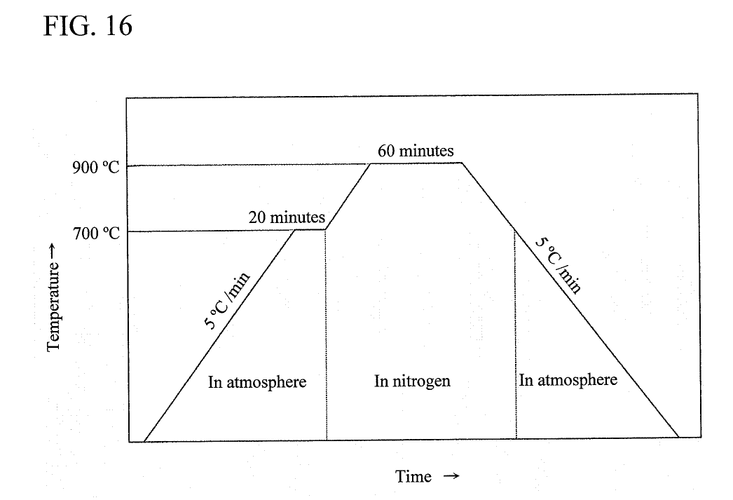

In this example, the Cu—Al alloy powders of the present invention (average particle diameter: 1 μm) were used for the paste for the wiring 30. Moreover, nitrocellulose with a less residue of carbon was used as the binder, and butyl acetate was used as the solvent. The multilayer wiring board (five layers) of FIG. 15 was manufactured using the paste for the wiring 30 made of these materials. Since the Cu—Al alloy of the present invention (Cu-10 wt % Al was used in this example) does not completely oxidize up to 800 degrees C. in an oxidizing atmosphere, as shown in a temperature profile in FIG. 16, heat treatment conditions when firing this multilayer wiring board were determined as follows: firing was performed in the atmosphere up to 700 degrees C., and performed in a nitrogen atmosphere at a temperature from 700 to 900 degrees C. The Cu—Al alloy was maintained in a nitrogen atmosphere at 900 degrees C. for 60 minutes, and returned in the atmosphere when cooled to 700 degrees C. Since removal of the binder was almost completed before the temperature reached 700 degrees C., the manufactured multilayer wiring board was fired precisely. Moreover, the wiring 30 made of the Cu—Al alloy hardly oxidized, and the electric resistance did not increase. Additionally, no void in the vicinity of the wiring due to reaction with the glass was generated, either. Consequently, the multilayer wiring board of high performance and lower costs can be provided now. The temperature profile and atmosphere used for the heat treatment are not limited to this, and by containing Al not less than 15% by weight, the same effect was able to be obtained also in the heat treatment in the atmosphere at 900 degrees C.

### EXPLANATION OF REFERENCE NUMERALS

10 frontplate
11 back plate
12 partition wall
13 sealing material
15, 16, and 17 fluorescent bodies of red, green and blue
18 display electrode
19 address electrode
20 ultraviolet ray
21, 22, 402 dielectric layers
23 protective layer
24 and 26 metal Cr film
25 Cu—Al alloy film
27 pure Cu disk
28 pure Al
30 wiring
31 green sheet
32 through hole
401 Cu-based material
403 bubble

What is claimed is:

1. An electronic component comprising a wiring that contacts a glass or a glass ceramics member, wherein the wiring is formed of a binary alloy made of two elements of Cu and Al, and contains not more than 50.0% by weight of Al and a balance of unavoidable impurities.

2. The electronic component according to claim 1, wherein the wiring contains 1.0 to 15.0% by weight of Al.

3. The electronic component according to claim 1, wherein the wiring is formed on a substrate by a sputtering method, covered with the glass or the glass ceramics member, and fired.

4. The electronic component according to claim 1, wherein the wiring further includes glass, is formed on a substrate by a printing method, covered with the glass or the glass ceramics member including the glass, and fired.

5. The electronic component according to claim 1, wherein
the wiring is formed in a hole part and a surface of a green sheet made of the glass or the glass ceramics member by a printing method,
the green sheet is stacked and fired, and
the wiring is incorporated into the green sheet thus stacked in three dimensions.

6. The electronic component according to any one of claims 1 to 5, wherein the electronic component is any of a system on film, a tape carrier package, a low temperature co-fired ceramics multilayer wiring board, a plasma display, a liquid crystal display, an organic EL display, and a solar cell.

7. A wiring material in which at least powders of a conductive metal material and glass powders are mixed, wherein the powders of the conductive metal material are made of a binary alloy made of two elements of Cu and Al, and contain not more than 50.0% by weight of Al and a balance of unavoidable impurities.

8. The wiring material according to claim 7, wherein the powders of the conductive metal material contain 1.0 to 15.0% by weight of Al.

9. The wiring material according to claim 7, wherein the powders of the conductive metal material have a form of molded particle powders.

10. The wiring material according to claim 7, wherein the wiring material is formed of 65 to 90% by volume of the powders of the conductive metal material, and 10 to 35% by volume of the glass powders.

11. A paste material for wiring, comprising:
the powders of the conductive metal material and the glass powders according to claim 7;
a binder; and
a solvent.

12. A sputtering target for producing by a sputtering method a wiring material formed of a binary alloy made of two elements of Cu and Al, and containing not more than 50.0% by weight of Al and a balance of unavoidable impurities, wherein the sputtering target has any of a structure in which Cu or Al is embedded in the sputtering target as a single metal, and a structure formed of a binary alloy of Cu and Al.
